(19) United States
(12) Patent Application Publication
(10) Pub. No.: US 2026/0121319 A1
(43) Pub. Date: Apr. 30, 2026

(54) SOCKET CONTACT

(71) Applicant: SAAB AB, Linköping (SE)

(72) Inventors: Christian Olsson, Hammarö (SE); Rick Hedell, Kristinehamn (SE); Bo Bäckman, Karlskoga (SE)

(21) Appl. No.: 19/470,977

(22) PCT Filed: Apr. 5, 2024
(86) PCT No.: PCT/SE2024/050327

§ 371 Date: Sep. 30, 2025

(30) Foreign Application Priority Data
Apr. 11, 2023 (SE) 2300029-2

(51) Int. Cl. H01R 12/71

(52) U.S. Cl. CPC H01R 12/718

(57) ABSTRACT

The disclosure relates to a socket contact (10) for a printed circuit board (30), the socket contact being arranged for receiving a contact pin (20). The socket contact comprises a planar structure (11), a first circular through opening (12), being arranged at the centre of the planar structure (11), a plurality of through slits (13) extending outwards from the first circular through opening (12) forming a plurality of tongues (15) of the planar structure (11). The tongues is radially extending towards the first circular through opening (12), and each slit (13) is radially outwardly extending into a second circular through opening (14). The second circular through openings has a diameter (d2) which is smaller than the diameter (d1) of the first circular through opening (12), but larger than the width (w) of the corresponding slit (13). The disclosure also relates to a method (200) for arranging the socket contact (10) in contact with a contact pin.

### TECHNICAL FIELD

The present application relates to a socket contact, an electrical connector comprising the socket contact, a printed circuit board comprising the socket contact and to a method for arranging the socket contact in contact with a contact pin.

### BACKGROUND ART

A socket contact may be used for rigid and flexible printed circuit boards as an electronic contact element for connecting electronic components together.

A problem of known socket contacts are that they have a height of several millimetres and that they are very difficult to pass through narrow passages.

There is thus need for an improved socket contact which is small and compact in size and which provides for a high electrical conductivity.

### SUMMARY OF THE INVENTION

An object of the present disclosure is to provide a solution for a socket contact where some of the above-identified problems are mitigated or at least alleviated.

According to a first aspect there is provided a socket contact for a printed circuit board, the socket contact being arranged for receiving a contact pin. The socket contact comprises a planar structure, a first circular through opening, being arranged at the centre of the planar structure, a plurality of through slits extending outwards from the first circular through opening forming a plurality of tongues of the planar structure, said tongues radially extending towards the first circular through opening. Each slit radially outwardly extends in a second circular through opening, wherein the second circular through openings has a diameter which is smaller than the diameter of the first circular through opening, but being larger than the width of the corresponding slit.

The socket contact provides for a large number of contact points between the socket contact and a contact pin. Thus, the socket contact provides for a high contact force between the socket contact and a contact pin with regard to its shape and size, and especially with regard to its height. A high contact force is important in order avoid poor electrical contact between the socket contact and a contact pin being inserted into the socket contact.

The socket contact has a compact size, especially with regard to its height.

The socket contact is possible to reuse the since the plurality of tongues of the socket contact are not permanently deformed upon use.

The socket contact is resistant towards vibrations due to its compact design and due to that the tongue portions keep the contact pin in position.

According to some embodiments, the plurality of slits are equally spaced and the number of plurality of equally spaced slits is in the range of three to twelve, preferably four to eight, most preferably the number of plurality of equally spaced slits is six.

The proposed number of slits provides for a high contact force between the socket contact and a contact pin to which the socket contact is arranged in contact with. The equally spaced slits provides for an equal contact force between each of the tongues and the contact pin.

According to some embodiments, the length of each slit extends in the range of ⅕ to ⅘, preferably in the range of ⅖ to ⅗ of a length extending from the periphery of the first circular through opening to an outer end of the planar structure.

The proposed length of each slit provides for a high mechanical strength of the socket contact.

According to some embodiments, the planar structure is substantially circular or has the shape of a square, hexagonal, or octagonal.

The planar structure may have any shape being suitable for the space on the printed circuit board where the socket contact is to be attached. A substantially circular shape has the advantage of allowing the socket contact being self-centred when being attached to a printed circuit board.

According to some embodiments, each of the plurality of tongues being arranged as a bent tongue portion being bent upwards with respect to the planar structure. Preferably each bent tongue portion being arranged at an angle in the range of 145°-90°, preferably in the range of 135°-100°, most preferably in the range of 125°-110°, with respect to the planar structure.

The upwardly bent tongue portion provides for an improved guidance of the contact pin upon arrangement of the socket contact in contact with a contact pin. The bent portions eliminates, or at least reduces, the risk that the surface of the contact pin is scratched upon arrangement of the socket contact in contact with a contact pin. If the surface of the contact pin becomes scratched, there is a risk that an oxide layer is formed on the contact pin which may impair the electrical conductivity of the contact pin and thus also of an electrical connector comprising the socket contact and the contact pin.

According to some embodiments, each of the plurality of upwardly bent tongue portions extends in the range of ½ to ⅙, most preferably ¼ to ⅕ of the length of each of the plurality of slits.

The proposed extension of the upwardly bent portions provides for improved guidance of the contact pin upon arrangement of the socket contact in contact with a contact pin

According to some embodiments, each of the second circular through openings has a diameter which is in the range of 5.0 to 1.5 times, preferably 4.0 to 2.0, most preferably 3.0 to 2.5 times larger than the width of each of the plurality of equally spaced slits.

The second circular through openings provides for a high mechanical strength of the socket contact and thus a reduced risk of breaking the socket contact upon arranging the socket contact in contact with a contact pin.

According to some embodiments, the planar structure comprises an electrically conductive material, such as a copper alloy or stainless steel.

This provides for electrical conductivity between the socket contact and the contact pin.

According to some embodiments, the total height of the socket contact is 0.8 to 0.4 mm, preferably 0.6 to 0.5 mm.

Thus, the socket contact has a compact size, especially with regard to its height.

According to some embodiments, the thickness of the planar structure is in the range of 0.09 to 0.03 mm, preferably in the range of 0.08 to 0.04 mm, most preferably in the range of 0.07 to 0.05 mm.

Thus, the socket contact has a compact size, especially with regard to its height.

According to some embodiments, the planar structure comprises a coating of an electrically conducting material, such as Au, said coating being arranged on both sides of the planar structure.

The coating of an electrically conducting material provides for a high electrical conductivity of the socket contact. The coating also provides for resistance towards oxidization in harsh environments, such as in presence of salt, moisture and/or gunpowder.

According to some embodiments, the coating has a thickness of 1.0 to 0.5 μm, preferably of 0.8 to 0.6 μm.

The proposed thickness of the coating provides for resistance towards oxidization of the planar structure. The proposed thickness further provides for a resistant attachment to the printed circuit board, i.e. a resistant soldering joint. When the coating is thicker than 1 μm, there is a risk that the attachment to the printed circuit board becomes deteriorated, for example that the soldering joint becomes brittle.

According to some embodiments, the contact force between the socket contact and a contact pin being inserted into the socket contact is 2 to 10 N, preferably 3 to 9 N, most preferably 5 to 7 N.

The high contact force provides for a good electrical contact between the socket contact and the contact pin. It also provides for a socket contact being resistant towards vibrations.

According to a second aspect there is provided an electrical connector comprising the socket contact and a contact pin.

The electrical connector provides for the same advantages as discussed in relation to the socket contact above.

According to a third aspect there is provided a printed circuit board comprising the socket contact.

The printed circuit board comprising the socket contact provides for the same advantages as the socket contact above.

According to a fourth aspect there is provided a method for arranging the socket contact in contact with a contact pin. The method comprises the steps of: providing a printed circuit board, providing a through hole of the printed circuit board and attaching the socket contact to the printed circuit board such that the through hole of the printed circuit board is aligned with the first circular through opening of the socket contact. The method further comprises the step of inserting the contact pin through the through hole of the printed circuit board and the first circular through opening from the bottom side of the socket contact, such that the plurality of bent tongue portions of the socket contact are in electrical contact with the contact pin.

The proposed method provides for the same advantages as the proposed socket contact.

Further, the socket contact is easy to arrange in contact with a contact pin since there is no need for specialized equipment for arranging the socket contact in contact with a contact pin and the arrangement of the socket contact in contact with a contact pin can be performed in room temperature.

According to some embodiments, attaching the socket contact to the printed circuit board comprises soldering, gluing with an electrically conducting glue or attaching the socket contact by means of a casing being attached to the printed circuit board and being arranged for clamping the socket contact to the printed circuit board.

The proposed attaching the socket contact to the printed circuit board provides for a secure attachment of the socket contact to the printed circuit board, thereby providing a socket contact being resistant towards vibrations and which provides for a good electrical contact between the socket contact and the printed circuit board.

### BRIEF DESCRIPTION OF THE DRAWINGS

FIG. 1a schematically illustrates the upper side of a socket contact according to an example of the disclosure.

FIG. 1b schematically illustrates a side view of a socket contact according to an example of the disclosure.

FIG. 2 schematically illustrates a planar view of a socket contact according to an example of the disclosure.

FIG. 3 schematically illustrates sectional view of a printed circuit board comprising a socket contact and a contact pin according to an example of the disclosure.

FIG. 4 schematically illustrates an example of attachment of the socket contact by means of a casing onto the printed circuit board.

FIG. 5 schematically illustrates a method of arranging a socket contact in contact with a contact pin according to the disclosure.

### DETAILED DESCRIPTION

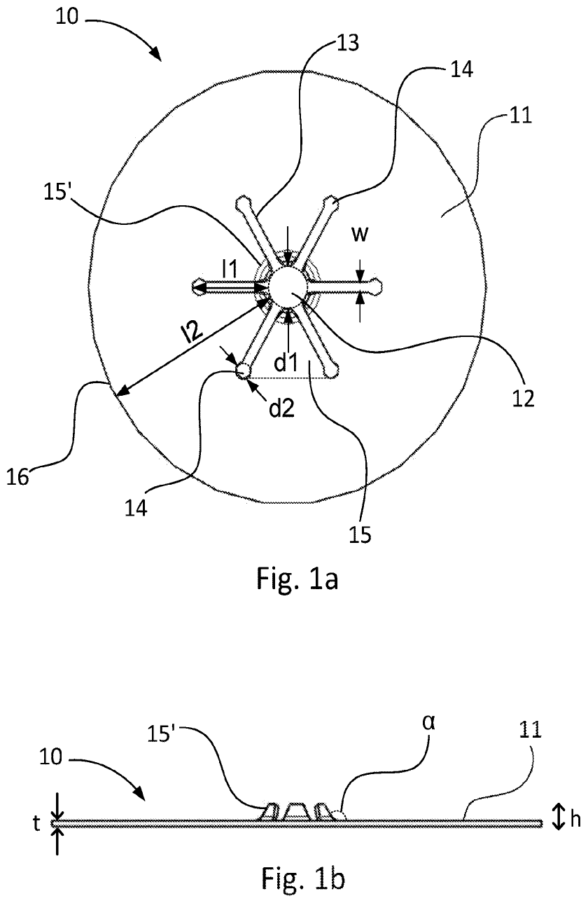

FIG. 1a schematically illustrates the upper side of a socket contact 10, according to an example of the present disclosure. FIG. 1b schematically illustrates a side view of a socket contact according to an example of the present disclosure.

By socket contact, also known as a female contact, is meant an electrical component being arranged for receiving a contact pin from its bottom side, also known as a male contact.

As illustrated in FIG. 1a, the socket contact 10 comprises a planar structure 11. The planar structure 11 may be substantially circular or may have the shape of a square, hexagonal, or octagonal. The socket contact 10 comprises a first circular through opening 12, being arranged at the centre of the planar structure 11. The socket contact comprises a plurality of through slits 13 extending outwards from the first circular through opening 12 forming a plurality of tongues 15 of the planar structure 11, said tongues radially extending towards the first circular through opening 12. Each slit 13 is radially outwardly extending into a second circular through opening 14. Each of the plurality of tongues 15 of the socket contact 10 in FIGS. 1a and 1b are bent, forming upwardly bent tongue portions 15′. As shown in FIG. 1b, the socket contact has a total height, h, when viewed from the side. The total height h of the socket contact 10 may be 0.8 to 0.4 mm, preferably 0.6 to 0.5 mm. The thickness t of the planar structure 11 may be in the range of 0.09 to 0.03 mm, preferably in the range of 0.08 to 0.04 mm, most preferably in the range of 0.07 to 0.05 mm.

The circular through opening 12, the plurality of through slits 13 and the second circular through openings 14 may preferably be manufactured by etching of the planar structure. Other methods of manufacturing are possible as well, such as punching of the planar structure.

As illustrated in FIGS. 1a and 1b, each of the plurality of tongues may be arranged as a bent tongue portion 15′ being bent radially towards the first circular through opening. The purpose of the bent tongue portions 15′ of the socket contact is to provide for an improved guidance of the contact pin upon arrangement of the socket contact 11 in contact with the contact pin Preferably each bent tongue portion 15′ is arranged at an angle a in the range of 145°-90°, preferably in the range of 135°-100°, most preferably in the range of 125°-110°, with respect to the planar structure 11. The bent tongue portions 15′ also provides for an elastic deformation of the tongues upon insertion of the contact pin, so that the tongues still are able to press back on the contact pin.

The socket contact may be arranged on a printed circuit board (PCB), such as a rigid printed circuit board or a flexible printed circuit board. As mentioned above, the socket contact may be arranged for receiving a contact pin, thereby forming an electrical connector comprising the socket contact and the contact pin. The printed circuit board comprising the socket contact may be arranged in any type of electronic devices, such as computers, cellular phones etc. where electric components need to be electrically connected to each other. In one example, the electrical connector comprising the socket contact and a contact pin may be used for connecting a plurality of printed circuit boards together. In one example, the socket contact may be used for communication transmission. In yet an example, the socket contact may be used for power supply between electrical components.

The printed circuit board may comprise a plurality of socket contacts, wherein the plurality of socket contacts may be of the same or different dimensions and/or materials.

In yet an example, the socket contact may be used for prevent an inserted shaft from pulling out, such as a retaining ring, for example a lock washer.

Each second circular through opening has a diameter d2 which is smaller than the diameter d1 of the first circular through opening 12, but being larger than the width w of the corresponding slit 13.

The number of plurality of equally spaced slits 13 may be is in the range of three to twelve, preferably four to eight is in the range of three to twelve, preferably four to eight, most preferably the number of plurality of equally spaced slits 13 is six. If the number of plurality of equally spaced slits is fewer than six, a higher contact force between the socket contact and a contact pin is obtained as compared to when the number of plurality of equally spaced slits is six to eight. However for a socket contact having fewer than six equally spaced slits, there is a high risk of breaking the socket contact due to stresses arising in the planar structure. In one example, when the plurality of equally spaced slits is eight, the contact force is about 30% lower as compared to when the plurality of slits is six. The contact force between the socket contact and the contact pin being inserted into the socket contact may be in the range of 2 to 10 N, preferably 3 to 9 N, most preferably 5 to 7 N, for a socket contact wherein the number of plurality of equally spaced slits is in the range of six to eight. By contact force is meant the force that occurs as a result of the socket contact, in particular the upwardly bent tongue portions, and the contact pin being inserted into the socket contact. The contact force is also affected by the diameter d2 of the second circular through openings, the larger diameter of the second circular openings, the lower contact force is provided. Other parameters affecting the contact force is the number and length of equally spaced slits, the thickness t of the planar structure, material of the planar structure and the coating, diameter d1 of the first circular through opening.

The length l1 of each slit 13 may extend in the range of ⅕ to ⅘, preferably in the range of ⅖ to ⅗ of a length l2 extending from the periphery of the first circular through opening 12 to an outer end 16 of the planar structure 11.

Each of the second circular through openings 14 may have a diameter d2 which is in the range of 5.0 to 1.5 times, preferably 4.0 to 2.0, most preferably 3.0 to 2.5 times larger than the width w of each of the plurality of equally spaced slits 13.

Each of the plurality of upwardly bent tongue portions 15′ may extend in the range of ½ to ⅙, most preferably ¼ to ⅕ of the length 11 of each of the plurality of slits 13.

The thickness t of the planar structure 11 may be in the range of 0.09 to 0.03 mm, preferably in the range of 0.08 to 0.04 mm, most preferably in the range of 0.07 to 0.05 mm.

The upwardly bent portions 15′ (not including the thickness of the planar structure) may reach 0.2 mm above the planar structure at most.

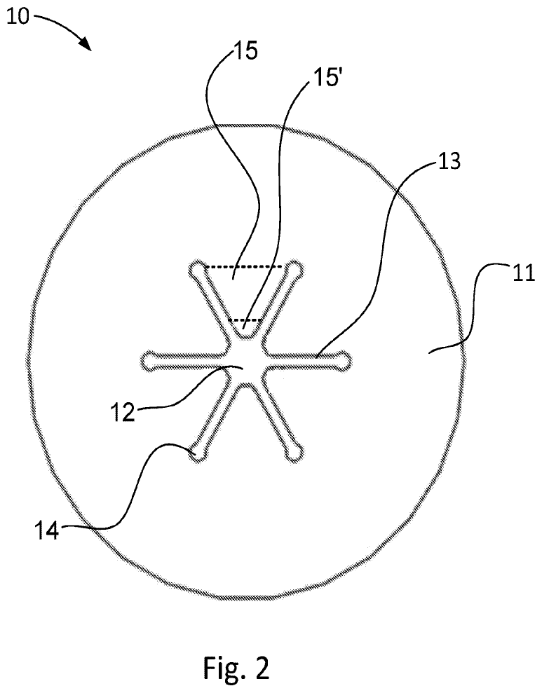

FIG. 2 schematically illustrates a planar view of a socket contact according to an example of the disclosure. FIG. 2 schematically illustrates the socket contact 10 prior to forming the upwardly bent portions 15′ being shown in FIGS. 1a and 1b. The socket contact 10 comprises a planar structure 11. The socket contact 10 comprises a first circular through opening 12, being arranged at the centre of the planar structure 11. The socket contact comprises a plurality of through slits 13 extending outwards from the first circular through opening 12 forming a plurality of tongues 15 of the planar structure 11, wherein the tongues radially extending towards the first circular through opening 12. Each slit 13 is radially outwardly extending into a second circular through opening 14.

The planar structure may comprise an electrically conductive material, such as a copper alloy or stainless steel. Preferably, the entire planar structure comprises the same material.

The planar structure may comprise a coating of an electrically conducting material, said coating being arranged on both sides of the planar structure. The purpose of the coating is to improve the electrical conductivity of the planar structure. In addition, the coating provides for an improved resistance towards oxidation of the socket contact. Thus, the coating may be chosen from a material which is not prone to oxidization. In one example, the electrically conducting coating may be Au. In one example, the purity if of the Au is at least 99.5%, preferably about 99.7%. The coating may have a thickness of 1.0 to 0.5 μm, preferably of 0.8 to 0.6 μm. A thicker coating provides for an improved resistance towards oxidation, however the when the coating is thicker than 1 μm, there is a risk that the attachment to the printed circuit board becomes deteriorated, for example that the soldering joint becomes brittle. For coatings having a thickness of above 1 μm, there is thus need for removing a portion of the coating before attaching the socket contact to the printed circuit board, resulting in more process steps upon arranging the socket contact in contact with a contact pin.

The coating may be arranged on both sides of the planar structure. The coating may be uniform and cover the entire surface. Alternatively, the coating may be provided on only one side of the planar structure, i.e. on the side which the tongues will press against the contact pin.

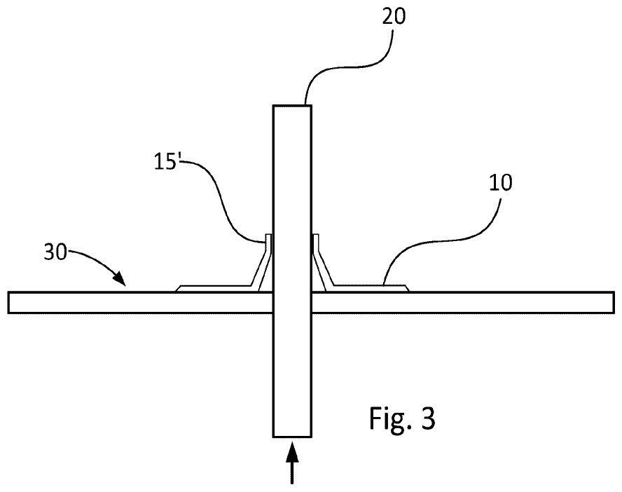

FIG. 3 illustrates a printed circuit board 30 comprising the socket contact 10. The contact pin 20 may be arranged through a through hole of the printed circuit board 30 and the first circular through opening of the socket contact, such that the plurality of tongues 15′ of the socket contact are in electrical contact with the contact pin 20. Each of the plurality of tongues 15 being arranged as a bent tongue portion 15′ being bent upwards with respect to the planar structure. The arrow in FIG. 3 indicates the direction of which a contact pin preferably is inserted through the first circular through opening of the socket contact, i.e. when arranging the socket contact in contact with a contact pin. Thus, the contact pin is inserted from the bottom side of the socket contact, i.e. from the opposite side of which the tongues are bent upwards.

The contact pin 20 may have an elongated shape, preferably the contact pin has a cylindrical shape. In one example, the entire contact pin comprises an electrically conducting material, such as gold (Au), copper (Cu) or silver (Ag). The contact pin may further comprise a coating of an electrically conducting material, such as gold, copper or silver. In the latter example, the coating preferably covers the entire contact pin. The contact pin preferably has a diameter which is slightly larger as compared to the first circular through opening being arranged at the centre of the planar structure. Thereby, the tongues are pushed apart and are bent upon insertion of the contact pin through the through hole of the printed circuit board and the first circular through opening of the socket contact. If the contact pin has a diameter which is too large in relation to the socket contact, the tongues of the socket contact may break upon arranging the socket contact in contact with the contact pin. If the contact pin has a diameter which is too small in relation to the socket contact, the contact force becomes too low. A low contact force may result in an impaired the electrical contact between the socket contact and the contact pin due to loose electrical connection between the socket contact and the contact pin. In one example, the contact pin may have a diameter of about 0.75 mm. The diameter of the contact pin is larger than the second circular through opening 14.

The bent tongue portions 15′ may be provided prior to the arranging the socket contact 10 in contact with a contact pin 20. The reason for providing the bent tongue portions 15′ prior to arranging the socket contact in contact with the contact pin is that the bent portions eliminates, or at least reduces, the risk that the surface of the contact pin is scratched by the tip of the tongue portion upon arrangement of the socket contact in contact with the contact pin.

A printed circuit board may comprise a plurality of socket contacts and contact pins. The through hole board may preferably be arranged within the printed circuit board prior to arrangement of the socket contact and the contact pin. The through hole may be provided by means any suitable method of providing a through hole, such as drilling or punching. The through hole of the printed circuit board may be aligned with the first circular through opening of the socket contact.

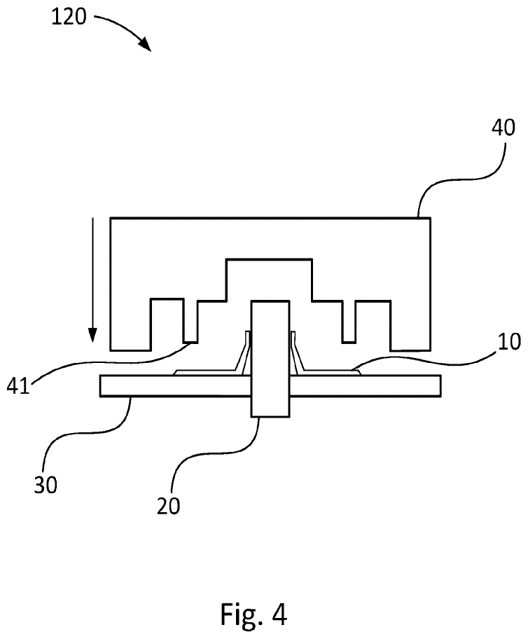

In one example, the socket contact may be attached to the printed circuit board by soldering and/or gluing with an electrically conducting glue. Alternatively, and as shown in FIG. 4, the socket contact 10 may be attached to the printed circuit board 30 by means of a casing 40 being attached to the printed circuit board and being arranged for clamping the socket contact to the printed circuit board 30. The casing 40 may be attached to the printed circuit board by means of fastening means (not shown), such as screws, rivets and/or bolts. Alternatively, the casing 40 may be attached to the printed circuit board by means of soldering and/or gluing. In one example, the casing 40 may have portions 41 being arranged to clamp the end portions of the socket contact 10. In one example, each socket contact may be attached to the printed circuit board by one casing 40. In another example, the casing 40 may be arranged to attach a plurality of socket contacts to the printed circuit board 30.

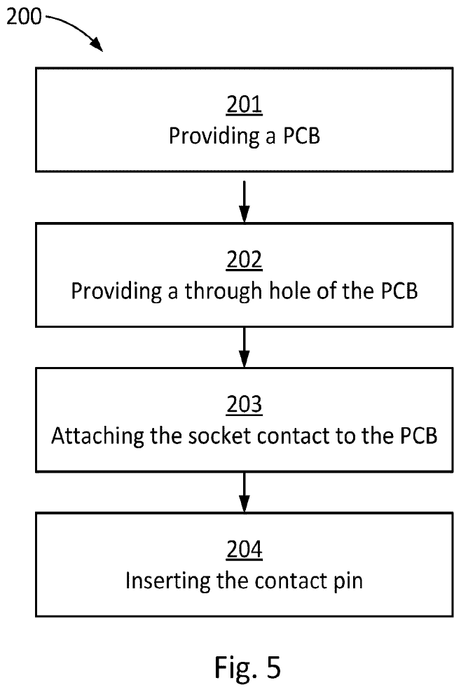

FIG. 5 schematically illustrates a method 200 of connecting a socket contact to a contact pin according to the disclosure. The method comprises the steps of providing a printed circuit board 201 and providing a through hole of the printed circuit board 202. The method further comprises the step of attaching the socket contact 10 to the printed circuit board 203 such that the through hole of the printed circuit board is aligned with the first circular through opening 12 of the socket contact 10. The method further comprises a step of inserting the contact pin 20 through the through hole of the printed circuit board and the first circular through opening 12 from the bottom side of the socket contact 204, such that the plurality of bent tongue portions 15′ of the socket contact are in electrical contact with the contact pin 20. Preferably and as discussed above, the bent tongue portions 15′ may be provided prior to the arranging the socket contact 10 in contact with a contact pin 20. The reason for providing the bent tongue portions 15′ prior to arranging the socket contact in contact with the contact pin is that the bent portions eliminates, or at least reduces, the risk that the surface of the contact pin is scratched by the tip of the tongue portion upon arrangement of the socket contact in contact with the contact pin. If the surface is scratched there is a risk that an oxide layer is formed on the contact pin which may impair the electrical conductivity of the contact pin and thus also of an electrical connector comprising the socket contact and the contact pin. Upon inserting the contact pin through the through hole of the printed circuit board and the first circular through opening 12 from the bottom side of the socket contact the tongues may be further bent from the centreline of the first circular opening.

The printed circuit board may be a rigid or flexible printed circuit board. The printed circuit board comprising the socket contact may be arranged in any type of electronic devices, such as computers, cellular phones, where electric components need to be electrically connected to each other. The through hole may be provided by means any suitable method of providing a through hole, such as drilling or punching. The step of attaching the socket contact 10 to the printed circuit board 203 may comprise soldering, gluing with an electrically conducting glue, or attaching the socket contact by means of a casing 40 being attached to the printed circuit board and being arranged for clamping the socket contact to the printed circuit board.

In the latter case, the casing 40 may be attached to the printed circuit board by means of fastening means (not shown), such as screws, rivets and/or bolts. Alternatively, the casing 40 may be attached to the printed circuit board by means of soldering and/or gluing. In one example, the casing 40 may have portions 41 being arranged to clamp the end portions of the socket contact 10. In one example, each socket contact may be attached to the printed circuit board by one casing 40. In another example, the casing 40 may be arranged to attach a plurality of socket contacts to the printed circuit board 30.

The method of arranging the socket contact in contact with a contact pin preferably takes place in room temperature, but it may take place in any other temperature. Thereby, there is no need for specialized equipment for arranging the socket contact in contact with a contact pin.

It should be understood that the dimensions, such as the thickness t of the planar structure, total height h of the socket contact etc. and materials of the socket contact, may be varied depending on the application of the socket contact.

1. A socket contact (10) for a printed circuit board (30), the socket contact being arranged for receiving a contact pin (20), said socket contact comprising:
a planar structure (11),
a first circular through opening (12), being arranged at the centre of the planar structure (11), and
a plurality of through slits (13) extending outwards from the first circular through opening (12) forming a plurality of tongues (15) of the planar structure (11), said tongues radially extending towards the first circular through opening (12),
wherein:
each slit (13) radially outwardly extends into a second circular through opening (14),
the second circular through openings has a diameter (d2) which is smaller than the diameter (d1) of the first circular through opening (12), but being larger than the width (w) of the corresponding slit (13).

2. The socket contact (10) according to claim 1, wherein the plurality of slits are equally spaced and wherein the number of plurality of equally spaced slits (13) is in the range of three to twelve, preferably four to eight, most preferably the number of plurality of equally spaced slits (13) is six.

3. The socket contact (10) according to any of claim 1, wherein the length (11) of each slit (13) extends in the range of ⅕ to ⅘, preferably in the range of ⅖ to ⅗ of a length (12) extending from the periphery of the first circular through opening (12) to an outer end (16) of the planar structure (11).

4. The socket contact (10) according to claim 1, wherein the planar structure (11) is substantially circular or has the shape of a square, hexagonal, or octagonal.

5. The socket contact (10) according to claim 1, wherein each of the plurality of tongues (15) being arranged as a bent tongue portion (15′) being bent upwards with respect to the planar structure, preferably each bent tongue portion (15′) being arranged at an angle (α) in the range of 145°-90°, preferably in the range of 135°-100°, most preferably in the range of 125°-110°, with respect to the planar structure (11).

6. The socket contact (10) according to claim 5, wherein each of the plurality of upwardly bent tongue portions (15′) extends in the range of ½ to ⅙, most preferably ¼ to ⅕ of the length (11) of each of the plurality of slits (13).

7. The socket contact (10) according to claim 1, wherein each of the second circular through openings (14) has a diameter (d2) which is in the range of 5.0 to 1.5 times, preferably 4.0 to 2.0, most preferably 3.0 to 2.5 times larger than the width (w) of each of the plurality of equally spaced slits (13).

8. The socket contact (10) according to claim 1, wherein the planar structure (11) comprises an electrically conductive material, such as a copper alloy or stainless steel.

9. The socket contact (10) according to claim 1, wherein the total height (h) of the socket contact (10) is 0.8 to 0.4 mm, preferably 0.6 to 0.5 mm.

10. The socket contact (10) according to claim 1, wherein the thickness (t) of the planar structure (11) is in the range of 0.09 to 0.03 mm, preferably in the range of 0.08 to 0.04 mm, most preferably in the range of 0.07 to 0.05 mm.

11. The socket contact (10) according to claim 1, wherein the planar structure (11) comprises a coating of an electrically conducting material, such as Au, said coating being arranged on both sides of the planar structure.

12. The socket contact (10) according to claim 11, wherein the coating has a thickness of 1.0 to 0.5 μm, preferably of 0.8 to 0.6 μm.

13. The socket contact (10) according to claim 1, wherein the contact force between the socket contact and a contact pin being inserted into the socket contact is in the range of 2 to 10 N, preferably 3 to 9 N, most preferably 5 to 7 N.

14. An electrical connector (100) comprising the socket contact (10) according to claim 1, and a contact pin (20).

15. A printed circuit board (30) comprising the socket contact (10) according to claim 1.

16. A method (200) for arranging the socket contact (10) according to claim 1 in contact with a contact pin (20), the method comprising the steps of:
providing a printed circuit board (201),
providing a through hole of the printed circuit board (202),
attaching the socket contact (10) to the printed circuit board (203) such that the through hole of the printed circuit board is aligned with the first circular through opening (12) of the socket contact (10), and
inserting the contact pin (20) through the through hole of the printed circuit board and the first circular through opening (12) from bottom side of the socket contact (204), such that the plurality of bent tongue portions (15′) of the socket contact are in electrical contact with the contact pin (20).

17. The method (200) according to claim 16, wherein attaching the socket contact (10) to the printed circuit board (203) comprises soldering, gluing with an electrically conducting glue or attaching the socket contact by means of a casing (40) being attached to the printed circuit board and being arranged for clamping the socket contact to the printed circuit board.
